(19) United States
(12) Patent Application Publication
(10) Pub. No.: US 2012/0282471 A1
(43) Pub. Date: Nov. 8, 2012

(54) ROOFING GRANULES INCLUDING BASE PARTICLES AND A COATING

(75) Inventors: Rosiana Aguiar, Paris (FR); Bernard Nghiem, Arsy (FR); Regine Faure, Paris (FR)

(73) Assignee: Certain Teed Corporation, Valley Forge, PA (US)

(21) Appl. No.: 13/101,838

(22) Filed: May 5, 2011

(51) Int. Cl. B32B 5/16; B05D 5/06; C23C 16/44; B05D 7/00

(52) U.S. Cl. 428/403; 427/213

(57) ABSTRACT

A roofing product can include roofing granules that can include base particles and a coating covering the base particles of the roofing granules. In a particular aspect, the coating can include a compound that includes a metallic element; and nitrogen, carbon, or a combination of nitrogen and carbon. In another aspect, the coating has a reflectivity of at least approximately 17% for a radiation having wavelengths in a range of 1000 nm to 2500 nm. In a further aspect, the particular coating has a coating reflectivity no greater than 99% of a TiO₂ reflectivity for such radiation. A coating can be formed on a base particle of a roofing granule using a fluidized bed. In a particular aspect, coating can be performed as a chemical vapor deposition or a sol-gel process. If needed or desired, the roofing granules can be doped to achieve their desired properties.

### FIELD OF THE DISCLOSURE

The present disclosure relates to roofing granules and processes of forming the roofing granules and, more particularly, to roofing granules including bases particles and a coating covering the base particles and to processes of forming the roofing granules.

### RELATED ART

Roofing materials are susceptible to heating due to radiation emitted from the sun. Some roofing materials may reflect little near-infrared (“NIR”) radiation and consequently absorb substantial solar heat. This absorption of solar heat typically results in elevated temperatures in the environment surrounding the exposed building material. The same or other roofing materials may have low emissivity which reduces the emission of absorbed heat. The absorbed solar heat, low emissivity, or both may reduce the lifetime of the roofing materials.

### BRIEF DESCRIPTION OF THE DRAWINGS

Embodiments are illustrated by way of example and are not limited in the accompanying figures.

FIG. 1 includes an illustration of a cross-sectional view of a roofing granule in accordance with an embodiment described herein.

FIG. 2 includes an illustration of a cross-sectional view of a roofing granule in accordance with another embodiment described herein.

FIG. 3 includes an illustration of a cross-sectional view of a roofing granule in accordance with another embodiment described herein.

FIG. 4 includes an illustration of a cross-sectional view of a roofing granule in accordance with another embodiment described herein.

FIG. 5 includes a depiction of a portion of a fluidized bed reactor that can be used with a chemical vapor deposition process described herein.

FIG. 6 includes a depiction of a portion of a fluidized bed reactor that can be used with a sol-gel process described herein.

FIG. 7 includes an illustration of a substrate used for a roofing product.

FIG. 8 includes an illustration of the substrate of FIG. 7 after the substrate has been coated with a bituminous material.

FIG. 9 includes an illustration of the substrate of FIG. 8 after applying roofing granules along an exposed surface of the substrate.

FIG. 10 includes the reflectivity spectrum for the samples described later in this specification.

FIG. 11 includes a plot of solar reflectance as a function of L* for the samples described later in this specification.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be used in this application.

Before addressing details of the embodiments described below, some terms are defined or clarified. The term “averaged” is intended to mean an average (i.e., an arithmetic mean), a median, or a geometric mean.

The term “near infrared radiation” (also, “NIR radiation”) is intended to mean a radiation spectrum having wavelengths corresponding to 700 nm to about 2500 nm.

The term “visible light” is intended to mean a radiation spectrum having wavelengths corresponding to 400 nm to 700 nm.

In this specification, color may be expressed as a color space that is specified by a set of 1976 CIE (Commission Internationale de L′Eclairage) color space coordinates of L*, a*, and b*, wherein L* represents lightness of the color (L*=0 is black, and L*=100 indicates diffuse white; specular white may be higher), a* represents a position between red/magenta and green (a* negative values indicate green while positive values indicate magenta), and b* represents a position between yellow and blue (b* negative values indicate blue and positive values indicate yellow).

As used herein, the terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise. For example, when a single item is described herein, more than one item may be used in place of a single item. Similarly, where more than one item is described herein, a single item may be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in reference books and other sources within the structural arts and corresponding manufacturing arts.

Roofing granules can include base particles and a coating covering the base particles. In a particular aspect, the coating can include a compound that includes a metallic element; and nitrogen, carbon, or a combination of nitrogen and carbon. In another aspect, the coating has a reflectivity of at least approximately 17% for radiation having wavelengths in a range of 1000 nm to 2500 nm, and an emissivity of at least approximately 55%. The roofing granules can have a wide range of colors including beige, yellow, green, brown, dark gray, and potentially other colors while still having the reflectivity and emissivity previously mentioned. The coating can be formed on the base particle using a fluidized bed. In a particular aspect, coating can be performed as a chemical vapor deposition or a sol-gel process. If needed or desired, the roofing granules can be doped to achieve their desired properties. After reading this specification, skilled artisans will appreciate that other applications and processes can be used without departing from the concepts described herein.

FIG. 1 includes an illustration of a cross-sectional view of a roofing granule 10 that includes a base particle 12 and a coating 14 covering the base particle 12. The base particle 12 can include suitably sized particles of naturally occurring materials such as talc, slag, granite, silica sand, greenstone, andesite, porphyry, marble, syenite, rhyolite, diabase, greystone, quartz, slate, trap rock, basalt, and marine shells can be used, as well as recycled manufactured materials such as crushed bricks, concrete, porcelain, fire clay, and the like. In an embodiment, the base particles 12 have a particle size between #8 and #50 U.S. mesh, and in another embodiment, the base particles 12 have a particle size between #8 and #50 U.S. mesh. Exemplary base particles include roofing base granules with a particle size between #10 and #40 U.S. mesh or algae-resistant roofing granules, both available from CertainTeed Corporation of Piedmont, Mo., USA. Although the base particle 12 is illustrated as a circle, skilled artisans will appreciate that the actual shape of the base particle 12 is irregular. The circular shape is used to improve understanding of the concepts described herein.

The coating 14 can be characterized by its properties. The reflectivity of a particular coating may depend on process used to make the coating, the thickness of the coating, or metrology equipment or metrology technique used to obtain the data used to determine reflectivity. For example, a TiOxNy coating that is formed by chemical vapor deposition to a thickness of approximately 9 microns may have a different reflectivity as compared to a TiOxNy coating that is formed using a different deposition technique or to a significantly different thickness or when different metrology equipment or techniques are used. To allow for better comparisons of reflectivities, such reflectivities may be expressed as relative measurements. Accordingly, a “TiO₂ reflectivity” can be used to provide a relative comparison between coatings. The TiO₂ reflectivity is intended to mean a reflectivity of a coating consisting essentially of TiO₂ that is formed using the same coating technique to approximately the same thickness as the coating to which TiO₂ is being compared, wherein the same metrology equipment and technique are used to obtain the data for reflectivity. For example, a TiOxNy coating that is formed by chemical vapor deposition to a thickness of approximately 9 microns can be compared to a TiO₂ coating formed by the chemical vapor deposition to a thickness of approximately 9 microns, wherein date for the TiOxNy and TiO₂ coatings are obtained using the same metrology equipment and metrology technique. The TiOxNy coating may have a reflectivity that is less than the TiO₂ reflectivity. In an embodiment, many of the coatings described herein have a reflectivity that is no greater than 99% of the TiO₂ reflectivity. In another embodiment, such coatings can have a reflectivity that is at least approximately 50%, at least approximately 65%, at least approximately 80%, or at least approximately 90% of the TiO₂ reflectivity.

In an embodiment, the coating can have a reflectivity of at least approximately 17% for radiation having wavelengths in a range of 1000 nm to 2500 nm. In another embodiment, the reflectivity for the radiation is at least approximately 20%. In a particular embodiment, the reflectivity is in a range of approximately 20 to approximately 30%. In still another embodiment, the maximum reflectivity for the radiation is no greater than 29%. In one embodiment, the coating has an emissivity of approximately 55%. In a particular embodiment, the emissivity is at least approximately 70%. In another embodiment, the emissivity is no greater than approximately 98%.

The coating can also be characterized by its visual appearance. The colors can include beige, yellow, green, brown, dark gray, and potentially other colors. Each color may be more precisely defined by color space using a set of L*, a*, and b* coordinates. As points of reference, an exemplary base particle 12 can be characterized by a set of L*, a*, and b* coordinates of 39.2, 3.0, and 2.4, respectively, and another exemplary base particle coated with TiO₂ can be characterized by a set of L*, a*, and b* coordinates of 54.4, 2.0, and 5.0, respectively. In an embodiment, the coating can have an a* value that is less than 2.0, and in a particular embodiment, is less than approximately 1.0. In another particular embodiment, the a* value is negative. In a further embodiment, the coating can have a b* value that is greater than 5.0, and in a particular embodiment, is greater than approximately 6.0. In another embodiment, the b* value can be less than 5.0. In a particular embodiment, when the a* value is less than 2.0, the b* value can be less than 5.0, or at least 2.4, or at least approximately 3.0.

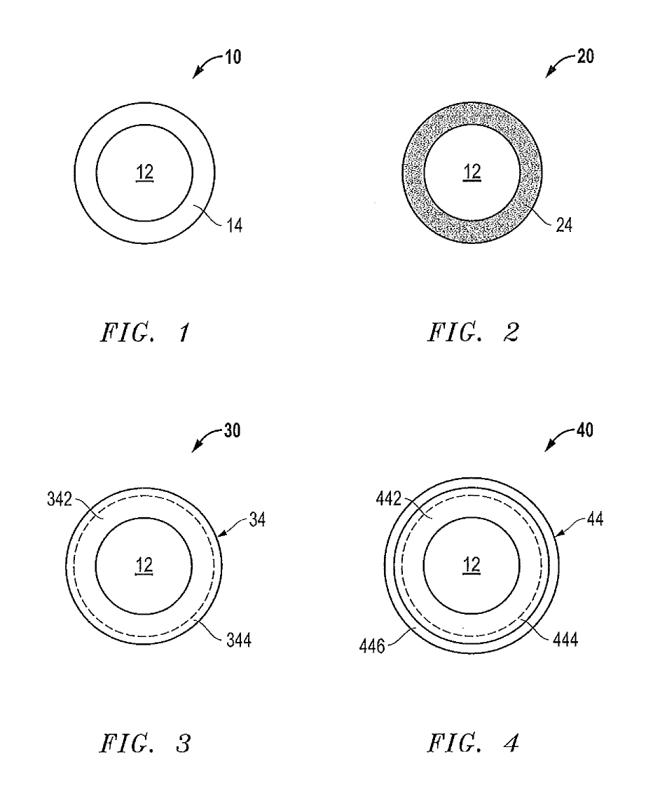

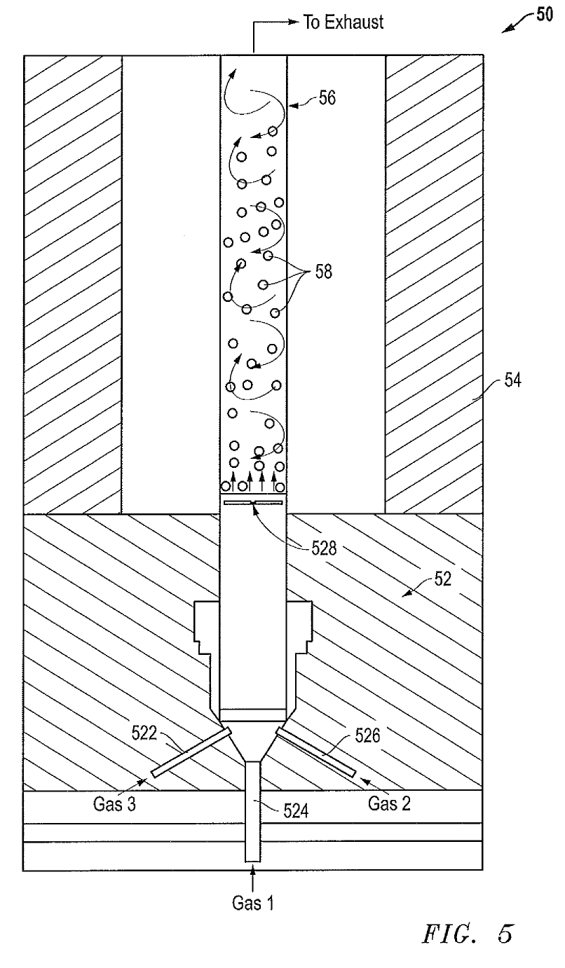

Many properties of the coating 14 have been given. In other embodiments, the coatings 24, 34, and 44 in FIGS. 2, 3, and 4, respectively, can include any or all of the properties previously described with respect to coating 14. The significance of the coatings 24, 34, and 44 is described with respect to compositions of the coatings later in this specification.

Potential compositions of the coatings are addressed. The coating 14 can include a compound. The compound can include a metallic element, oxygen, and any of nitrogen, carbon, or both. In an embodiment, the compound can be a metal oxynitride or a metal oxycarbide. The metallic element can include a transition metal. In a particular embodiment, the metallic element can include Ti, Nb, Ta, V, Zr, Zn, La, Ca, Ba, Sr, Nd, Ga, B, or any combination thereof. In a more particular embodiment, Ti is the only metallic element within the compound. For example, the compound can be TiOₓN_{y} or TiOₓC_{y}, wherein x has a value of 0 formula units (“f.u.”) to less than 2 f.u., and y has a value greater than 0 f.u. to 1 f.u.

In another embodiment, more than one metallic element may be present within the coating 14. For example, the formula can be A_{w}DₓO_{y}N_{z} or A_{w}DₓO_{y}Cₐ, wherein A can include Ti, Nb, Ta, V, Zr, or Zn; D can include La, Ca, Ba, Sr, Nd, Ga, or B; w has a value of 0.5 formula units (“f.u.”) to 2 f.u.; x has a value of 0.5 f.u. to 2 f.u.; y has a value greater than 0 formula units (“f.u.”) to 5 f.u.; z has a value greater than 0 f.u. to 2 f.u; and a has a value greater than 0 f.u. to 2 f.u.

In the compound, the amount of nitrogen or carbon may vary. When expressed as a percentage of the sum of oxygen and nitrogen atoms or as the sum of oxygen and carbon atoms, the percentage of nitrogen atoms or carbon atoms may be as high as 100%. In a particular embodiment, up to approximately 3% nitrogen may be incorporated into titanium oxide without forming a separate phase. For example, in FIG. 1, the coating 14 may have a substantially uniform composition. When more than 3% nitrogen is present within the coating, a TiOₓN_{y} phase and a separate TiN phase may be formed. In FIG. 2, the roofing granule 20 has a coating 24 with the TiOₓN_{y} phase and a TiN phase distributed throughout the coating 24. Thus, within the TiN phase, titanium is bonded only to nitrogen and not to oxygen. Thus, more than one compound may be present within the coating 24.

FIG. 3 includes a cross-sectional view of a roofing granule 30 having a coating 34 that is doped. A metal oxide layer can be formed over the base particle 12. An outer portion 344 can be doped with nitrogen or carbon atoms. An inner portion 342 may be substantially undoped and include the metal oxide. Thus, the oxygen content within the coating 34 will be relatively higher at a location closer to the base particle 12 and relatively lower at a location farther from the base particle 12. In a particular embodiment, the inner portion 342 can consist essentially of TiO₂, and the outer portion 344 can include TiOₓN_{y}. In another embodiment, substantially all of the metal oxide layer can be doped. The nitrogen content may or may not be substantially uniform throughout the coating 34.

In still a further embodiment, the roofing granule 40 coating 44 can include more than one layer. In this particular embodiment, the coating 44 includes an outer layer 446 that provides a desired appearance. In a particular embodiment, the outer layer 446 may not adhere well to the base particle 12 or an inner portion 442 of an inner layer. The outer portion 444 of the inner layer may have a composition different from the base particle 12 or the inner portion 442 of the inner layer, wherein such composition improves adhesion of the outer layer 446 to the remainder of the roofing granule 40.

The actual thickness of the coating 14, 24, 34, or 44 over the base particle 12 may vary from location to location due to the irregular surface of the base particle 12. Thus, the thickness of the coating can be characterized by an averaged thickness. Any of the coatings described herein can have an averaged thickness of at least approximately 50 nm. In an embodiment, the averaged thickness may be at least approximately 500 nm, and in another embodiment, at least approximately 1.1 microns. In a further embodiment, the averaged thickness may be no greater than 50 microns, in still a further embodiment, no greater than approximately 20 microns, and in yet a further embodiment, the averaged thickness is no greater than 15 microns. In a particular embodiment, the averaged thickness is in a range of approximately 2 microns to approximately 10 microns. With respect to the coating 24, 34, and 44, each of the portions and layers can have averaged thicknesses as described herein.

The roofing granules can be made using a fluidized bed process. In one set of embodiments, a chemical vapor deposition (“CVD”) fluidized bed process can be used, and in another set of embodiments, a sol-gel fluidized bed process can be used. The different sets of embodiments are described in more detail below.

The fluidized bed reactor for the CVD process can include a grid and a deposition chamber. The grid is used to keep the granules in the hot zone of the fluidized bed and let the carrier gas and reaction gases flow through. A dust separator is optional and can be used to remove relatively fine particles from gases that are being exhausted from the fluidized bed reactor. For the CVD process, reactive gas inlets can be plumbed so that the reactive gases do not contact each other until the reactive gases are within the fluidized bed.

In one embodiment, a fluidized bed reactor 50 as illustrated in FIG. 5 can be used for the CVD process. The reactor includes a feed section 52, a heater 54, and a deposition chamber 56. As illustrated, the feed section 52 includes gas lines 522, 524, and 526, wherein different gases can be feed into the deposition chamber. In a particular embodiment, the gas line 522 can provide a metal-containing source gas, the gas line 524 can provide a nitrogen-containing source gas, and the gas line 526 can provide a carrier gas. In another embodiment, more or fewer gas inlets may be used. Although not illustrated, valves and controls are used to control the flow of gases in the gas lines 522, 524, and 526. The gases are kept separate before entering the reaction chamber 56.

The heater 54 is used to provide heat to the deposition chamber 56. The deposition chamber 56 includes a material that does not significantly react with the reaction or product gases within the deposition chamber 56. Because roofing granules 58 will contact the wall of the deposition chamber 56, the material along the inner surface may be abrasion resistant. In a particular embodiment, the material along the inner surface of the deposition chamber 56 may have a hardness that is harder than the material of the base particles (before coating), the coating deposited onto the base particles, or both materials. In another particular embodiment, the material along the inner surface can include quartz, alumina, silicon nitride, aluminum nitride, or the like. In a particular embodiment, the deposition chamber can consist essentially of any of the foregoing materials or may include a metal-containing tube with a liner that consists essentially of any of the foregoing materials. For example, the deposition chamber 56 can be quartz tube. The roofing granules 58 remain within the deposition chamber during deposition, and gases exit the deposition chamber and are sent to an exhaust.

The fluidized bed reactor 50 may operate as an open, atmospheric pressure reactor having an inert gas shower, such as N₂, a noble gas, CO₂ or any combination thereof, to help keep oxygen from outside the reactor 50 from entering the deposition chamber 56. In another embodiment, the fluidized bed reactor 50 can be a sealed system, which may allow reactant gas flows to be reduced compared to the open system.

FIG. 5 illustrates the roofing granules 58 as they are being coated in the reaction chamber 56. The deposition chamber 56 can be charged with base particles that are to be coated, and the deposition chamber 56 can be heated using the heater 54 to the desired reaction temperature. In an embodiment, the temperature can be at least approximately 300° C., and in another embodiment, the temperature can be less than approximately 800° C. The particular temperature may depend on the particular composition of the coating.

A carrier gas flows through the gas line 526 through the orifice plate 528, and into the deposition chamber 56. The carrier gas can flow at a rate sufficient to fluidize the bed. The carrier gas can be relatively inert with respect to the base particles, the reactive gases, and coating to be formed on the base particles. The carrier gas can include N₂, a noble gas, CO₂, or any combination thereof.

The reactive gas or gases can flow into the deposition chamber while the granules are fluidized. When a metal oxynitride coating is being formed, a metal-containing gas flows through the gas line 522 and a nitrogen-containing gas flows through the gas line 524. When a metal oxycarbide coating is being formed, the organometallic gas flow through the gas line 522, and substantially no reactive nitrogen-containing gas flows into the reaction chamber 56. In an embodiment, the metal-containing gas includes an organometallic compound. In a particular embodiment, the metal-containing gas includes tetraisopropyl orthotitanate, titanium tetraisobutoxide, tetra(cyclopentadienyl)niobium, lanthanum nitrate hexahydrate, Tris(i-propylcyclopentadienyl)lanthanum, monobutyl tin chloride (MBTCl), or the like.

The reactive gases can include a nitrogen-containing gas. In a particular embodiment, the nitrogen-containing gas can include NH₃, a nitrogen oxide, N₂H₄, another suitable nitrogen-containing gas, or any combination thereof.

The ratio of the metal-containing gas molar flow rate to the nitrogen-containing gas molar flow rate may depend on the number of atoms within the compounds of the metal-containing gas and the nitrogen-containing gas. For example, on a per mole basis, N₂H₄ can provide twice as much nitrogen as NH₃. Many of the metal-containing gases include compounds that have only one metallic atom per compound. Thus, the product of the molar flow rate times the number of metal or nitrogen in the compound can determine how much metal or nitrogen is provided. A ratio of the metal-containing product (molar flow rate times the number of metal atoms within the metal-containing compound) to the nitrogen-containing product (molar flow rate times the number of nitrogen atoms within a nitrogen-containing compound) is at least approximately 1:500. In another embodiment, the ratio is less than approximately 1:2. In a particular embodiment, the ratio is in a range of approximately 1:150 to approximately 1:11.

When the coating includes a metal oxycarbide, an organometallic gas may be used and be only partly, not completely, oxidized. Thus, some of the carbon within the organometallic gas remains within the coating. Accordingly, a separate carbon-containing gas is not required. If needed or desired, the reactive gas can include an oxygen-containing gas. In a particular embodiment, the oxygen-containing gas can include air, O₂, O₃, N₂O, another suitable oxygen-containing gas, or any combination thereof.

The amount of oxygen-containing gas may be relatively lower than the nitrogen-containing gas or the carbon-containing gas. If the oxygen-containing gas is too high, an insufficient amount of nitrogen or carbon may be incorporated into the coating. A ratio of the metal-containing product (molar flow rate times the number of metal atoms within the metal-containing compound) to the oxygen-containing product (molar flow rate times the number of oxygen atoms within an oxygen-containing compound) is at least approximately 1:1. In another embodiment, the ratio is at least approximately 5:1. In a further embodiment, the ratio is at least approximately 11:1.

In another embodiment, a metal halide can be used for the metal-containing gas. In a particular embodiment, the metal-containing gas includes TiCl₄, TiBr₄, VCl₄, VF₅, or the like. When a metal halide is used and a metal oxynitride is being formed, an oxygen-containing gas may be used. When a metal halide is used and a metal oxycarbide is being formed, an oxygen-containing gas and a carbon-containing gas may be fed into the deposition chamber 56.

The previously described gases flowing into the fluidized bed reactor can form the roofing granules 58 that include the coating over the base particles. The flow of gases within the deposition chamber 56 is generally illustrated with arrows in FIG. 5. The coating can have any of the previously described properties, compositions, and thicknesses.

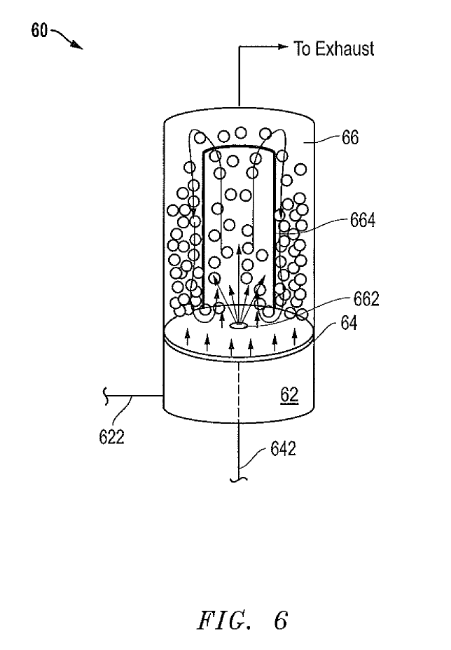

A sol-gel process can also be used to form the roofing granules that include the base particles and the coating. In a particular embodiment, the Wurster process for coating the particles can be used. FIG. 6 includes an illustration of a fluidized bed reactor 60 that includes a plenum chamber 62, an orifice plate 64, and a deposition chamber 66. The orifice plate 64 is disposed between the plenum chamber 62 and the deposition chamber 66. A carrier gas feed line 622 provides any of the previously described carrier gases to the plenum chamber 62. A solution feed line 642 provides a solution for the sol-gel process to a nozzle 662 within the deposition chamber 66. A separator 664 within the deposition chamber separates a deposition region where deposition occurs and a return region where coated base particles return after passing through the deposition region. A relatively higher gas flow rate of the carrier gas flows though the deposition region as compared to the return region. A dust separator (not illustrated) is optional and can be used to remove relatively fine particles from gases that are being exhausted from the fluidized bed reactor.

The deposition chamber can be charged with base particles that are to be coated, and the deposition chamber can be heated to the desired temperature. The solution that will be used to coat the base particles can include a metal oxide precursor and a solvent. The solvent can be water or an alcohol. Exemplary alcohols may have no more than 8 carbon atoms. In a particular embodiment, alcohols having 1 to 3 carbon atoms are used.

In a particular embodiment, the solution can include a metal alkoxide in distilled water. The solution may be stabilized with a hydroxylated component R—OH, such as alcohols, glycols, carboxylic acids (for example citric acid, acetic acid, or any other appropriate carboxylic acid) or β-diketones, (for example, acetylacetone) or any combination thereof. During coating, the metal alkoxide may react with the water to form a metal oxide and an alcohol that can evaporate. In a particular embodiment, the metal alkoxide can be a methoxide, an ethoxide, a propoxide, or the like. In a more particular embodiment, the metal alkoxide can be Ti(OCH₂CH₃)₄, Ti(OCH₂CH₂CH₂CH₃)₄, Sr(OC₄H₉)₂, Bi(OC₃H₇)₃, Ta(OC₂H₅)₅, Zr(OC₄H₉)₄, another suitable metal alkoxide, or the like.

In another particular embodiment, the solution can include a chlorinated metallic precursor in ethanol. In that case the chlorinated metallic precursor reacts exothermically with ethanol to form a metallic chloroethoxide and hydrochloric acid. Hydrolysis and condensation of the metallic chloroethoxide is ensured by water in environment air. In a more particular embodiment, the metal alkoxide can be derived from TiCl₄.

In a particular embodiment, organic additives can be added to adjust rheology of the solution or mechanical properties of the coatings. In a more particular embodiment, the organic additives can be polymer, such as polyethylene glycol or polyvinyl alcohol.

Alkoxides of any of the previously described metals may be used with respect to the coating (e.g., transition metals and the like). A titanium-based solution is commercially available as Vertec XI.900™-brand product from Johnson Matthey of London, United Kingdom. This product can be used as such or diluted, depending of the viscosity accepted by the fluidized bed. In a more particular embodiment, the product can be diluted in a range from approximately 1:1 to approximately 1:10 in distilled water. And in another more particular embodiment, the product can be diluted to approximately 1:5 in distilled water. In still another embodiment, the metal oxide can be in the form of particles within the solvent.

In an embodiment, the temperature used to coat the base particles may not exceed the boiling point of the solvent. When the solvent is water, the temperature may not exceed 100° C., when the solvent is ethanol, the temperature may not exceed 78° C., and when the solvent is 2-propanol, the temperature may not exceed 82° C. If the temperature is too low for the particular solvent used, the solvent may not vaporize sufficiently and the coated base particles may stick together. The temperature may be selected to achieve a vapor pressure of approximately 90 mm Hg; the corresponding temperatures for water, ethanol, and 2-propanol are 50° C., 32° C., and 36° C., respectively. In a particular embodiment, when water is the solvent, the temperature can be at least approximately 70° C. or may be no greater than approximately 80° C. In another particular embodiment, when ethanol is the solvent, the temperature can be at least approximately 51° C. or may be no greater than approximately 60° C. In a further particular embodiment, when 2-propanol is the solvent, the temperature can be at least approximately 57° C. or may be no greater than approximately 65° C. After reading this specification, skilled artisans will appreciate that the temperature for the coating portion of the sol-gel process may depend at least in part on the solvent used in the solution.

When the solution includes a hydrolyzed metal alkoxide, the temperature can be selected such that it is closer to the boiling point of the corresponding alcohol (product of the hydrolysis) as compared to water.

In an alternative embodiment, the solution can include metal oxide particles in the metal alkoxide solution or alone in a solvent. The metal oxide can include any of the metallic elements previously described. The solvent can include any of the previously described solvents.

A carrier gas flows into the plenum chamber, through the orifice plate, and into the deposition chamber. The carrier gas can flow at a rate sufficient to fluidize the bed. The carrier gas can be relatively inert with respect to the base particles, and the coating to be formed on the base particles. The carrier gas can include any of the previously described gases with respect to the CVD process.

After the fluidized bed is at its desired temperature and the carrier gas is flowing, the solution can be sprayed from a nozzle that is located within or just above the orifice plate near the middle (laterally) of the chamber. The solution coats the base particles, and the solvent or organic reaction product evaporates to leave a metal oxide coating on the base particles. When the solution includes a titanium-based precursor or TiO₂ particles, a coating of TiO₂ is formed on the base particles. Other metal-based precursors or other metal oxide particles can be used to coat the base particles. The thickness of the coating can be controlled by the deposition time, the concentration of the solution, the flow rate of the solution, or any combination thereof. Skilled artisans will appreciate that the foregoing variables may depend on the size or design of the particular fluidized bed used to coat the base particles.

The base particles that are coated with the metal oxide are subsequently doped with nitrogen, carbon, or both. In an embodiment, the doping can be performed in a kiln or other furnace. In a particular embodiment, a stationary kiln or a rotary kiln may be used. In an embodiment, the doping may be performed at a temperature of at least approximately 400° C., and, in another embodiment, at least approximately 500° C. In a further embodiment, the doping may be performed at a temperature no greater than approximately 1000° C., and, in another embodiment, no greater than approximately 900° C. In a particular embodiment, doping can be performed at a temperature in a range of approximately 500° C. to approximately 700° C.

In a particular embodiment for nitrogen doping, the nitrogen source can include amines, urea, biurea, NH₃, another suitable nitrogen source, or any combination thereof. At room temperature, urea is a solid and decomposes within the furnace. Another organic compound that is solid at room temperature can be used if it can decompose or volatilize at a temperature lower than the doping temperature. In a particular embodiment, the organic compound decomposes at a temperature in a range of approximately 100° C. to approximately 400° C. When urea is used, the amount of urea used can be in a range of approximately 10 weight % to approximately 200 weight % of mass of the coated base particles. When NH₃ is used, the amount of ammonia can be in a range of approximately 0.1 L to approximately 1 L of gas for 1 kg of granules.

For carbon doping, neatly any non-metallic carbon source may be used. Some carbon source can include an alkane, an alkene, an alkyne, a diene, an aromatic compound, a ketone, an aldehyde, an ether, an ester, an organic acid, a polymer, another suitable organic compound, or any combination thereof. All of these foregoing carbon sources decompose at a temperature no greater than 500° C. For ease of handling, a solid carbon source, such as a polymer may be used. An exemplary polymer includes a polyethylene glycol or a polyvinyl alcohol. If a gas is used, it can include methane, ethane, natural gas, or the like. The amount of the carbon source used can be in a range of approximately 10 weight % to approximately 200 weight % of mass of the coated base particles.

The furnace also includes a relatively inert gas. Any of the gases previously described with respect to the carrier gas may be used for the relatively inert gas during the furnace doping. The doping can be performed at substantially atmospheric pressure. In an embodiment, the doping temperature is at least approximately 500° C., and in another embodiment, the doping temperature is no greater than approximately 700° C. As the temperature increases, the reflectivity may decrease. In an embodiment, the doping may be performed for a time period of at least approximately 0.5 hours, and in another embodiment, the doping may be performed for a time period no greater than approximately 4 hours.

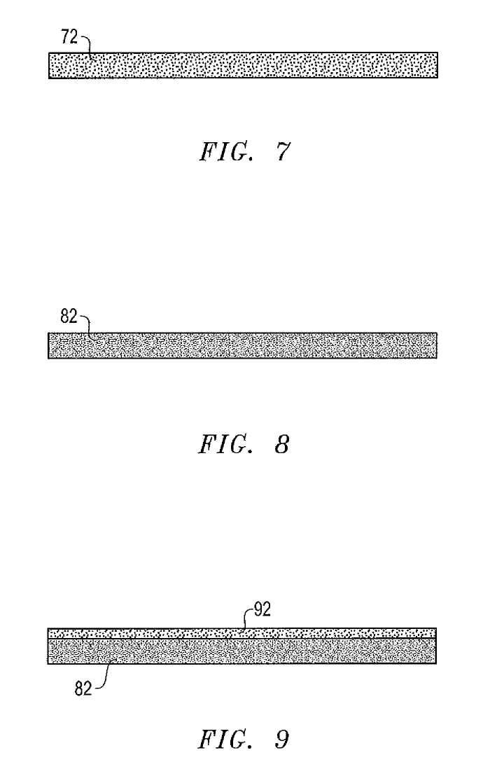

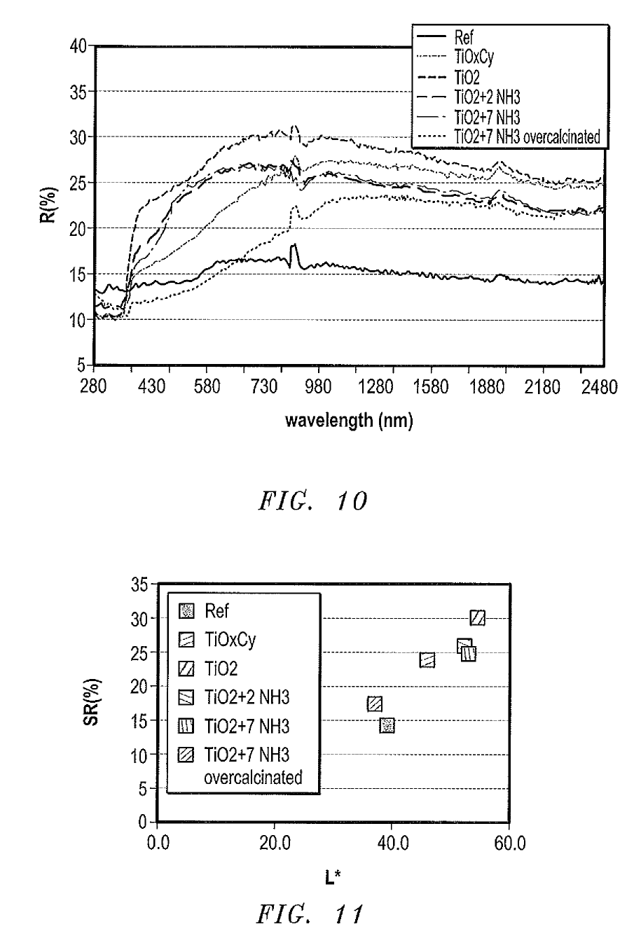

A roofing product can be formed using any of the previously described roofing granules made by any of the previously described processes. FIG. 7 includes an illustration of a cross-sectional view of a substrate 72 for the roofing product. The roofing product can include a shingle, a membrane, or the like. The substrate 72 can include a fiberglass mat, wood, cellulose, polyester, or another suitable substrate used for a roofing product. The substrate 72 is coated with a bituminous material to form the coated substrate 82, as illustrated in FIG. 8. The bituminous material can include asphalt, coal tar, a recycled roofing material, a synthetic bituminous material, or any combination thereof. If needed or desired, an additional coating of any of the foregoing bituminous materials may be applied to the coated substrate 82. Referring to FIG. 9, roofing granules 92 are applied to the coated substrate 82. The roofing granules 92 can be any of the previously described roofing granules, and are applied to the coated substrate 82 using a conventional technique. If another coating of bituminous material was applied the coated substrate 82, the roofing granules 92 are applied after the last layer of bituminous material is coated onto the coated substrate 82. Further processing may be performed if needed or desired. For example, a parting agent or release sheet (not illustrated) may be applied to the side of the roofing product opposite the roofing granules 92. In another embodiment, another sheet of roofing material may be laminated to the roofing product previously described to form a laminated roofing product. In another embodiment, a metallic sheet can be used as a substrate for a roofing product. An adhesive film or coating may be applied to the metallic sheet, and the roofing granules 92 can be applied to the adhesive film or coating. After reading the specification, skilled artisans will be able to form roofing products for their specific applications.

Many different aspects and embodiments are possible. Some of those aspects and embodiments are described below. After reading this specification, skilled artisans will appreciate that those aspects and embodiments are only illustrative and do not limit the scope of the present invention.

In a first aspect, a roofing product can include roofing granules, wherein the roofing granules include base particles and a coating covering the base particles of the roofing granules. The coating can include a compound that includes a metallic element and nitrogen, carbon, or a combination of nitrogen and carbon.

In an embodiment of the first aspect, the metallic element includes a transition metal element. In another embodiment, the metallic element includes Ti, Nb, Ta, V, Zr, Zn, La, Ca, Ba, Sr, Nd, Ga, B, or any combination thereof. In still another embodiment, the metallic element includes a first metallic element and a second metallic element, wherein the first metallic element includes Ti, Nb, Ta, V, Zr, or Zn, and the second metallic element includes La, Ca, Ba, Sr, Nd, Ga, or B.

In a further embodiment of the first aspect, Ti is an only metallic element within the compound. In a particular embodiment, the compound is TiOₓN_{y}, wherein x has a value of 0 f.u. to less than 2 f.u., and y has a value greater than 0 f.u. to 1 f.u. In a more particular embodiment, a percentage of nitrogen atoms in the coating is no greater than approximately 3%, wherein the percentage is 100% times a number of nitrogen atoms divided by a sum of oxygen and nitrogen atoms. In an even more particular embodiment, the coating has a phase including TiN. In another more particular embodiment, the coating further includes a layer of TiN. In another particular embodiment, the compound is TiOₓC_{y}, wherein x has a value of 0 f.u. to less than 2 f.u., and y has a value greater than 0 f.u. to 1 f.u.

In another embodiment of the first aspect, the coating has a substantially uniform composition. In still another embodiment, for a particular roofing granule, the coating has a first oxygen content at a first location and a second oxygen content at a second location, the base particle of the particular roofing granule is closer to the first location than to the second location, and the first oxygen content is greater than the second oxygen content. In yet another embodiment, the coating has an averaged thickness of at least approximately 50 nm, at least approximately 500 nm, or at least approximately 1.1 microns. In a further embodiment, the coating has an averaged thickness no greater approximately 50 microns or no greater approximately 20 microns. In a particular embodiment, the coating has an averaged thickness in a range of approximately 2 microns to approximately 10 microns.

In still a further embodiment of the first aspect, the coating has a reflectivity of at least approximately 17% for a radiation having wavelengths in a range of 1000 nm to 2500 nm. In a particular embodiment, the reflectivity is at least approximately 20%. In a more particular embodiment, a maximum reflectivity for the radiation is no greater than approximately 29%. In another embodiment, the coating has an emissivity of at least approximately 70%. In a particular embodiment, the emissivity is no greater than approximately 98%. In a still another embodiment, the coating has a reflectivity of at least approximately 17% for a radiation having a wavelength in a range of 1000 nm to 2500 nm, and an emissivity of at least approximately 55%. In a particular embodiment, a maximum reflectivity for the radiation is in a range of approximately 20% to 29%, and the emissivity is in a range of approximately 70% to approximately 98%.

In a further embodiment of the first aspect, an appearance of the coating is characterized by a color space having a set of L*, a*, and b* coordinates, wherein b* is greater than 5.0. In still a further embodiment, an appearance of the coating is characterized by a color space having a set of L*, a*, and b* coordinates, wherein b* is greater than approximately 6.0. In yet a further embodiment, an appearance of the coating is characterized by a color space having a set of L*, a*, and b* coordinates, wherein a* is greater than 2.0, and b* is at between 2.4 and 5.0. In a particular embodiment, b* is at least approximately 3.0.

In a second aspect, a roofing product can include roofing granules, wherein the roofing granules include base particles and a coating covering the base particles of the roofing granules. The coating can have a reflectivity of at least approximately 17% for a radiation having wavelengths in a range of 1000 nm to 2500 nm, and an emissivity of at least approximately 55%.

In an embodiment of the second aspect, an appearance of the coating is characterized by a color space having a set of L*, a*, and b* coordinates, wherein b* is greater than 5.0. In another embodiment, an appearance of the coating is characterized by a color space having a set of L*, a*, and b* coordinates, wherein b* is greater than approximately 6.0. In still another embodiment, an appearance of the coating is characterized by a color space by a set of L*, a*, and b* coordinates, wherein b* is less than 5.0. In a particular embodiment, a* is greater than 2.0. In a more particular embodiment, b* is at least 2.4. In another particular embodiment, b* is at least approximately 3.0.

In a further embodiment of the second aspect, the reflectivity is at least approximately 20%. In a particular embodiment, a maximum reflectivity for the radiation is no greater than 29%. In still a further embodiment, the coating has an emissivity of at least approximately 70%. In yet a further embodiment, the emissivity is no greater than approximately 98%. In another embodiment, a maximum reflectivity for the radiation is in a range of approximately 20% to approximately 30%, and the emissivity is in a range of approximately 70% to approximately 98%.

In still another embodiment of the second aspect, the coating has an averaged thickness of at least approximately 50 nm. In yet another embodiment, the coating has an averaged thickness of at least approximately 500 nm. In a further embodiment, the coating has an averaged thickness of at least approximately 1.1 microns. In still a further embodiment, the coating has an averaged thickness no greater than approximately 50 microns. In yet a further embodiment, the coating has an averaged thickness no greater than approximately 20 microns. In another embodiment, the coating has an averaged thickness in a range of approximately 2 microns to approximately 10 microns.

In a third aspect, a process of forming roofing granules can include flowing a gas into a fluidized bed reactor that includes base particles, and forming a coating along an exposed surface of the base particles while the base particles are within the fluidized bed reactor. The roofing granules can include the base particles and the coating. The coating can have a reflectivity of at least approximately 17% for radiation having wavelengths in a range of 1000 nm to 2500 nm, and an emissivity of at least approximately 55%. Alternatively, the coating can include a compound that includes a metallic element; and nitrogen, carbon, or a combination of nitrogen and carbon.

In an embodiment of the third aspect, the coating is formed by a chemical vapor deposition. In a particular embodiment, the gas includes a metal-containing gas; and a nitrogen-containing gas, a carbon-containing gas, or any combination thereof. In a more particular embodiment, the metal-containing gas includes an organometallic compound. In another more particular embodiment, the metal-containing gas includes tetraisopropyl orthotitanate, titanium tetraisobutoxide, tetra(cyclopentadienyl)niobium, lanthanum nitrate hexahydrate, or Tris(i-propylcyclopentadienyl)lanthanum, monobutyl tin chloride. In still another more particular embodiment, the metal-containing gas includes a metal halide. In a more particular embodiment, the metal-containing gas includes TiCl₄, TiBr₄, VCl₄, or VF₅.

In yet another more particular embodiment of the third aspect, the nitrogen-containing gas includes NH₃, a nitrogen oxide, N₂H₄, or any combination thereof. In an even more particular embodiment, flowing the gas includes flowing the metal-containing gas at a first molar flow rate and flowing the nitrogen-containing gas at a second molar flow rate. A first product is the first molar flow rate times a number of metal atoms within a metal-containing compound of the metal-containing gas, a second product is the second molar flow rate times a number of nitrogen atoms within a nitrogen-containing compound of the nitrogen-containing gas, and a ratio of the first product to the second product is at least approximately 1:500. In an even more particular embodiment, the ratio is less than approximately 1:2. In another even more particular embodiment, the ratio is in a range of approximately 1:150 to approximately 1:11.

In a further more particular embodiment of the third aspect, the carbon-containing gas includes an organic compound having no more than 8 carbon atoms. In an even more particular embodiment, flowing the gas includes flowing the metal-containing gas at a first molar flow rate and flowing the carbon-containing gas at a second molar flow rate. A first product is the first molar flow rate times a number of metal atoms within a metal-containing compound of the metal-containing gas, a second product is the second molar flow rate times a number of carbon atoms within a carbon-containing compound of the carbon-containing gas, and a ratio of the first product to the second product is greater than approximately 1:500. In an even more particular embodiment, the ratio is less than approximately 1:2. In another even more particular embodiment, the ratio is in a range of approximately 1:150 to approximately 1:11.

In another more particular embodiment, the gas further includes a carrier gas. In an even more particular embodiment, the carrier gas includes N₂, a noble gas, CO₂, or any combination thereof. In another even more particular embodiment, the carrier gas flows at a rate sufficient to fluidize the bed. In still another more particular embodiment, the gas further includes an oxygen-containing gas. In a further particular embodiment, forming the coating is performed at a temperature of at least approximately 500° C. In still another further embodiment, forming the coating is performed at a temperature less than approximately 800° C. In yet a further embodiment, forming the coating is performed at substantially atmospheric pressure.

In a further embodiment of the third aspect, the process further includes doping the coating with nitrogen, carbon, or a combination thereof. In a particular embodiment, forming the coating is performed using a sol-gel process. In another particular embodiment, the process further includes forming a solution including metal oxide compound and a solvent. In still another particular embodiment, the metallic element within the metal oxide compound includes a transition metal element. In a further particular embodiment, the metallic element within the metal oxide compound includes Ti, Nb, Ta, V, Zr, Zn, La, Ca, Ba, Sr, Nd, Ga, B, or any combination thereof. In still a further particular embodiment, the metal oxide compound includes a first metallic element and a second metallic element, the first metallic element includes Ti, Nb, Ta, V, Zr, or Zn, and the second metallic element includes La, Ca, Ba, Sr, Nd, Ga, or B. In yet a further embodiment, Ti is an only metallic element within the metal oxide compound. In another particular embodiment, the solvent includes water, an alcohol, or any combination thereof. In a more particular aspect, the metal oxide compound includes a metal alkoxide.

In still another particular embodiment of the third aspect, forming the coating is performed at a temperature no greater than a boiling point of the solvent. In a more particular embodiment, the temperature is no greater than approximately 80 percent of a difference between 0° C. and the boiling point of the solvent. In another more particular embodiment, the temperature is at least approximately 50 percent of a difference between 0° C. and the boiling point of the solvent. In still another more particular embodiment, the temperature is at least approximately 70 percent of a difference between 0° C. and the boiling point of the solvent.

In a further particular embodiment of the third aspect, the process further includes flowing a carrier gas at a flow rate sufficient to fluidize the bed. In still a further particular embodiment, the process further includes flowing a carrier gas. In a more particular embodiment, the carrier gas includes N₂, a noble gas, CO₂, or any combination thereof. In another more particular embodiment, the carrier gas flows at a rate sufficient to fluidize the bed. In an even more particular embodiment, the process further includes injecting the solution into a fluidized bed chamber while the bed is fluidized.

In another particular embodiment of the third aspect, doping the coating is performed using a nitrogen source. In a more particular embodiment, the nitrogen source includes an amine, urea, a biurea, NH₃, a nitrogen oxide, N₂H₄, or any combination thereof. In still another particular embodiment, doping the coating is performed using a carbon source. In a more particular embodiment, the carbon source includes an alkane, an alkene, an alkyne, a diene, an aromatic compound, a ketone, an aldehyde, an ether, an ester, an organic acid, a polymer, another suitable organic compound, or any combination thereof. In still another particular embodiment, doping the coating is performed using a solid doping source. In a more particular embodiment, doping the coating is performed at a temperature sufficient to decompose the solid source into a gas or volatilize the solid doping source. In another more particular embodiment, the solid doping source decomposes or volatilizes at a temperature no greater than approximately 400° C. In still another more particular embodiment, the solid doping source decomposes or volatilizes at a temperature of at least approximately 100° C.

In a further particular embodiment of the third aspect, doping is performed at a temperature no greater than approximately 1000° C. In still a further particular embodiment, doping is performed at a temperature of at least approximately 400° C. In yet a further embodiment, doping is performed for a time of no greater than approximately 4 hours. In another particular embodiment, doping is performed for a time of at least approximately 0.5 hours. In still another particular embodiment, during doping, an ambient with a doping chamber includes N₂, a noble gas, CO₂, or any combination thereof. In a further particular embodiment, doping is performed within a static kiln. In still a further particular embodiment, doping is performed within a rotary kiln. In yet a further particular embodiment, doping is performed at substantially atmospheric pressure.

Note that not all of the activities described above in the general description or the examples are required, that a portion of a specific activity may not be required, and that one or more further activities may be performed in addition to those described. Still further, the order in which activities are listed is not necessarily the order in which they are performed.

### EXAMPLES

The concepts described herein will be further described in the following examples, which do not limit the scope of the invention described in the claims. Some of the parameters below have been approximated for convenience.

### Example 1

Example 1 demonstrates that roofing granules can be formed from base particles that are coated with TiO₂ or TiOₓC_{y} using a CVD process carried out within a fluidized bed reactor.

TiO₂ and TiOₓC_{y} were deposited on approximately 5 g of the reference granules from CertainTeed using a CVD process. The precursor used for titanium was Titanium(IV) isopropoxide Ti{OCH(CH₃)₂}₄, “TiPT.” The flow of N₂ as carrying gas through a bubbler including TiPT precursor was 4 l/min. at 85° C., which corresponds to 5×10⁻⁴ mol/min. of TiPT delivered to the system. As used herein, volumetric flow rates are expressed at standard temperature and pressure (i.e., 0° C. and 1 atmosphere absolute pressure). The deposition time was fixed at 20 minutes. Oxygen (O₂) gas was used to help the oxidation of the organic part of the TiPT precursor, and the O₂ flow was 1 l/min. When the deposition was performed at 450° C., substantially pure TiO₂ was deposited on the granules. When the deposition was performed at 250° C., TiOₓC_{y} was found on the granules' surface. Thus, at 250° C., the temperature is too low to completely eliminate the organic part of the TiPT, even with the use of some O₂ during the deposition. The brownish color of the coating is a clear sign of the presence of carbon.

The reflectivity spectra of the samples were obtained from a Perkin Elmer Lambda 900-brand (UVNIS/NIR) Spectrometer that can operate from approximately 250 nm to approximately 2500 nm. Spectra obtained are shown in FIG. 10. In the visible light spectrum, the sample TiOₓC_{y} reflects less visible light than the TiO₂, which is expected due to the brownish color. At wavelengths from 800 nm to 2480 nm, both samples showed similar behavior. The results show that is possible to tailor the color of the coating while keeping the solar reflection (“SR”) acceptable at 800 nm, which is in the NIR region.

Emissivity data was collected using a Perkin Elmer Spectrum 100-brand FT-IR Spectrometer that can operate from approximately 2000 nm to approximately 25,000 nm. Reflectivity data is obtained as a function of wavelength, that is, at every 100 nm from starting at 2000 nm and ending at 25,000 nm. Emissivity at each wavelength, is determined by the equation below

εᵣ(λ)=1−r(λ).

wherein:

εᵣ(λ) is the emissivity at a particular wavelength; and

r(λ) is the reflectivity at the particular wavelength.

The emissivity values from the equation above are adjusted for Planck values at each wavelength λ using the equation below

ε_{P}(λ)=εᵣ(λ)×Pᵥ(λ,T)

wherein

ε_{P}(λ) is the emissivity adjusted for the Planck value at a particular wavelength; and

Pᵥ (λ,T) is the Planck value at the particular wavelength and the temperature at which measurements were taken, and is determined by the following equation.

Pᵥ(λ,T)=374200000/(λ5×e(14390/λT)−1).

Table 1 includes the deposition parameters used in forming the coating and optical properties of the coatings for the samples. “Ref” refers to a base particle (not coated). Emissivity data was not obtained for the base particles. The solar reflectance (SR) is determined by the following formula.

$$SR = \frac{{\int }_{280}^{2500} R ( λ ) Ir ( λ ) d λ}{{\int }_{280}^{2500} Ir ( λ ) d λ}$$

wherein:

R is the reflection in %, λ is the wavelength in nm, and Ir is the solar irradiance in W/m²/nm. Solar irradiance is tabled in literature, for example, at page 25 of Solar Technologies for Buildings by U. Eicker, John Wiley and Sons, West Sussex, England (2003). The thermal emissivity, TE, is determined by integrating ε_{P} over the 2000 nm to 25,000 nm spectrum.

TABLE 1

| | N₂ | O₂ | | | | | | | |
|---|---|---|---|---|---|---|---|---|---|
| | TiPT | (l/ | Temp. | Time | SR | | | | |
| Sample | (l/min) | min) | (° C.) | (min) | (%) | L* | a* | b* | TE |
| Ref | — | — | — | — | 14.3 | 39.2 | 3.0 | 2.4 | — |
| TiOₓC_{y} | 4 | 1 | 250 | 20 | 24.0 | 46.3 | 2.6 | 7.2 | 0.82 |
| TiO₂ | 4 | 1 | 450 | 20 | 30.0 | 54.4 | 2.0 | 5.0 | 0.81 |

### Example 2

Example 2 demonstrates that roofing granules can be formed from base particles that are coated with TiOₓN_{y} using a CVD process carried out within a fluidized bed reactor.

The TiOxNy coatings were deposited on the granules using TiPT as precursor for titanium. The flow of N₂ as carrying gas through a bubbler including TiPT precursor was 4 l/min. at 85° C., which corresponds to 5×10⁻⁴ mol/min. of TiPT delivered to the system. A nitrogen barrier was employed to avoid the entrance of air in the reaction chamber. Ammonia was used as nitrogen source in quantities of 2 l/min. and 7 l/min. The deposition time was 20 minutes at 450° C. The coating deposited with 2 l/min. of NH₃ showed light yellow color while the coating deposited with 7 l/min. of NH₃ showed dark yellow color. Both coatings show absorption up to 450 nm and the SR increases. One coating was deposited using 7 l/min. if NH₃ at 600° C. (also referred to as “overcalcinated”), this resulted in a dark brown color, with low reflectivity in the visible range but increase reflectivity in the NIR.

Table 2 includes the deposition parameters used in forming the coating and optical properties of the coatings for the samples. The data for the reference granules and TiO₂ are presented in Table 1 above.

TABLE 2

| | N₂ | | | | | | | | |
|---|---|---|---|---|---|---|---|---|---|
| | TiPT | NH₃ | Temp. | Time | SR | | | | |
| Sample | (l/min) | (l/min) | (° C.) | (min) | (%) | L* | a* | b* | TE |
| TiO₂ + 2 NH₃ | 4 | 2 | 450 | 20 | 25.7 | 52.8 | −2.0 | 11.4 | 0.80 |
| TiO₂ + 7 NH₃ | 4 | 7 | 450 | 20 | 24.9 | 53.0 | −1.9 | 13.1 | 0.81 |
| TiO₂ + 7 NH₃ | 4 | 7 | 600 | 20 | 17.5 | 37.2 | 3.0 | 4.7 | 0.81 |
| overcalcinated | | | | | | | | | |

FIG. 10 includes the reflectivity spectrum for the samples in Examples 1 and 2. A variety of different colors can be obtained and still provide good reflectance as compared to the reference granules. FIG. 11 includes a plot of solar reflectance as a function of L* for the samples in Examples 1 and 2.

### Example 3

Example 3 demonstrates that roofing granules can be formed from base particles that are coated using a sol-gel process carried out within a fluidized bed reactor, followed by a separate doping operation.

A base solution of titanium alkoxide is prepared by diluting 20 mL of Vertec XI.900™ (Johnson Matthey of London, UK) with 80 mL of distilled water. Then, 13.3 g of polyvinyl alcohol (molar mass 18000 g/mol, VWR International, Inc., West Chester, USA) are dissolved in the solution.

Approximately, 30 g of roofing granules are placed into a fluidized bed reactor at an initial temperature of approximately 90° C. The previously described solution is provided at a flow rate of 1 mL/minute. The process is continued for 30 minutes. During the coating process, the temperature in the bed decreases, and the final temperature is approximately 70° C. The average coating thickness is evaluated using image analysis of cross section scanning electron microscope (“SEM”) pictures. The average coating thickness is 10 μm.

A first heat treatment is performed for 1 hour at 500° C. in air to form TiO₂ and burn the organic part.

A second heat treatment is performed to dope the TiO₂. The doping is performed in a tubular non rotating furnace equipped with a quartz tube. In a ceramic container, 15 g of coated granules are mixed with 5 g of urea. The following procedure is used:
first the system is flushed for 2 hours with argon at room temperature to substantially eliminate oxygen,
then, still under argon, the furnace is heated to the temperature T at a heating rate of 300° C./hour,
the temperature T is maintained for 2 hours to completely decompose the urea into ammonia which then reduces TiO₂ into TiOₓN_{y},
finally, the temperature is decreased back to room temperature (the decrease is not controlled).

The exhaust fumes are neutralized with an HCl bath followed by a water bath.

The color of the obtained granules depends on the temperature T. The characteristics of the obtained granules are given in Table 3.

TABLE 3

| | | SR | | | | |
|---|---|---|---|---|---|---|
| Sample | Color | (%) | L* | a* | b* | TE |
| 500° C. | Dark greenish brown | 16.6 | 41.5 | 0.4 | 3.8 | 0.83 |
| 600° C. | Dark grey | 13.4 | 37.0 | 0.4 | −0.3 | 0.81 |
| 700° C. | Dark grey | 15.6 | 39.6 | 0.3 | −0.2 | 0.81 |

Certain features, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

1. A roofing product comprising roofing granules, wherein the roofing granules comprise:
base particles; and
a particular coating covering the base particles of the roofing granules, wherein the particular coating includes a compound that includes:
a metallic element; and
nitrogen, carbon, or a combination of nitrogen and carbon.

2. The roofing product of claim 1, wherein the metallic element includes a transition metal element.

3. (canceled)

4. The roofing product of claim 1, wherein:
the metallic element includes a first metallic element and a second metallic element;
the first metallic element includes Ti, Nb, Ta, V, Zr, or Zn; and
the second metallic element includes La, Ca, Ba, Sr, Nd, Ga, or B.

5. (canceled)

6. The roofing product of claim 1, wherein the compound is TiOₓN_{y} or TiOₓC_{y}, wherein:
x has a value of 0 f.u. to less than 2 f.u.; and
y has a value greater than 0 f.u. to 1 f.u.

7-12. (canceled)

13. The roofing product of claim 1, wherein the particular coating has an averaged thickness of at least approximately 50 nm.

14-18. (canceled)

19. The roofing product of claim 1, wherein the particular coating has a reflectivity of at least approximately 17% for a radiation having wavelengths in a range of 1000 nm to 2500 nm.

20. (canceled)

21. The roofing product of claim 1, wherein:
the particular coating has a coating reflectivity no greater than 99% of a TiO₂ reflectivity;
the coating reflectivity and the TiO₂ reflectivity are for a radiation having wavelengths in a range of 1000 nm to 2500 nm; and
the TiO₂ reflectivity is for another base particle having a TiO₂ coating that is formed using a same coating technique and substantially a same averaged thickness as the particular coating.

22-27. (canceled)

28. The roofing product of claim 1, wherein an appearance of the particular coating is characterized by a color space having a set of L*, a*, and b* coordinates, wherein b* is greater than 5.0.

29. (canceled)

30. The roofing product of claim 1, wherein an appearance of the particular coating is characterized by a color space having a set of L*, a*, and b* coordinates, wherein a* is greater than 2.0, and b* is at between 2.4 and 5.0.

31. (canceled)

32. A roofing product comprising roofing granules, wherein the roofing granules comprise:
base particles; and
a particular coating covering the base particles of the roofing granules, wherein:
the particular coating has a coating reflectivity no greater than 99% of a TiO₂ reflectivity;
the coating reflectivity and the TiO₂ reflectivity are for a radiation having wavelengths in a range of 1000 nm to 2500 nm; and
the TiO₂ reflectivity is for another base particle having a TiO₂ coating that is formed using a same coating technique and substantially a same averaged thickness as the particular coating.

33. The roofing product of claim 32, wherein the coating reflectivity is at least approximately 50% of the TiO₂ reflectivity.

34-36. (canceled)

37. The roofing product of claim 32, wherein an appearance of the particular coating is characterized by a color space having a set of L*, a*, and b* coordinates, wherein b* is greater than 5.0.

38. (canceled)

39. The roofing product of claim 32, wherein an appearance of the particular coating is characterized by a color space by a set of L*, a*, and b* coordinates, wherein b* is less than 5.0.

40-45. (canceled)

46. The roofing product of claim 32, wherein the coating has an averaged thickness of at least approximately 50 nm.

47-51. (canceled)

52. A process of forming roofing granules comprising:
flowing a gas into a fluidized bed reactor that includes base particles; and
forming a particular coating along an exposed surface of the base particles at least in part using the fluidized bed reactor,
wherein:
the roofing granules comprise the base particles and the particular coating; and
the particular coating:
has a reflectivity no greater than 99% of a TiO₂ reflectivity, wherein:
the coating reflectivity and the TiO₂ reflectivity are for radiation having wavelengths in a range of 1000 nm to 2500 nm; and
the TiO₂ reflectivity is for another base particle having a TiO₂ coating that is formed using a same coating technique and substantially a same averaged thickness as the particular coating; or
includes a compound that includes:
a metallic element; and
nitrogen, carbon, or a combination of nitrogen and carbon.

53. The process of claim 52, wherein the coating reflectivity is at least approximately 50% of the TiO₂ reflectivity.

54-56. (canceled)

57. The process of claim 52, wherein the particular coating is formed by a chemical vapor deposition.

58. The process of claim 57, wherein the gas comprises:
a metal-containing gas; and
a nitrogen-containing gas, a carbon-containing gas, or any combination thereof.

59-62. (canceled)

63. The process of claim 58, wherein:
the nitrogen-containing gas includes NH₃, a nitrogen oxide, N₂H₄, or any combination thereof; or
the carbon-containing gas comprises an organic compound having no more than 8 carbon atoms.

64-70. (canceled)

71. The process of claim 58, wherein the gas further comprises a carrier gas.

72-76. (canceled)

77. The process of claim 57, wherein forming the particular coating is performed at substantially atmospheric pressure.

78. The process of claim 52, further comprising doping the particular coating with nitrogen, carbon, or a combination thereof.

79. The process of claim 52, wherein forming the particular coating is performed using a sol-gel process.

80. The process of claim 79, further comprises forming a solution including metal oxide compound and a solvent.

81-94. (canceled)

95. The process of claim 77, wherein doping the particular coating is performed using a nitrogen source, a carbon source, or any combination thereof.

96-110. (canceled)
